(19) United States
(12) Patent Application Publication
(10) Pub. No.: US 2026/0076249 A1
(43) Pub. Date: Mar. 12, 2026

(54) Hybrid Bonding Strength and Thermal Conductivity Leveraging Inorganic-convertible Polymers

(71) Applicant: Apple Inc., Cupertino, CA (US)

(72) Inventors: Sanjay Dabral, Cupertino, CA (US); Jimin Yao, Cupertino, CA (US); SivaChandra Jangam, Milpitas, CA (US); Vidhya Ramachandran, Cupertino, CA (US)

(21) Appl. No.: 18/883,945

(22) Filed: Sep. 12, 2024

(51) Int. Cl. H01L 23/00

(52) U.S. Cl. CPC H10W 72/90; H10W 72/073; H10W 72/30; H10W 99/00; H10W 72/01365; H10W 72/07331; H10W 72/353; H10W 80/312; H10W 80/327; H10W 90/734; H10W 90/794

(57) ABSTRACT

Integrated circuit (“IC”) structures and electronic packages that utilized an inorganic-convertible polymer to improve bond strength and thermal conductivity are described. In one embodiment, the inorganic-convertible polymer acts as a side fill material to seal a die periphery and improve direct bonding strength. In another embodiment, the inorganic-convertible polymer acts as a thermal bonding layer to increase the thermal conductivity between a die and a thermal solution.

### BACKGROUND

### Field

Embodiments described herein relate to semiconductor packaging, and more particularly to improving hybrid bonding strength and thermal conductivity in electronic packages.

### Background Information

The current market demand for portable and mobile electronic devices such as mobile phones, personal digital assistants (PDAs), digital cameras, portable players, augmented reality/virtual reality (AR/VR) headsets, gaming, and other mobile devices requires the integration of more performance and features into increasingly smaller spaces. As a result, various multiple-die packaging solutions such as system in package (SiP) and package on package (PoP) have become more popular to meet the demand for higher die/component density devices.

There are many different possibilities for arranging multiple dies in an SiP. For example, vertical integration of dies in SiP structures has evolved into 2.5D solutions and 3D solutions. Hybrid bonding with metal-metal and dielectric-dielectric bonds using suitable techniques such as wafer-on-wafer (WoW) or chip-on-wafer (CoW) bonding is gaining more attention for mass production of high-density input/output (I/O) chips with ultra-small pad pitches. A traditional hybrid bonding sequence includes three main operations including dielectric-dielectric initial bonding at room temperature, heating to close dishing gap, and then further heating to compress metal-to-metal bonds. After the hybrid bonding process there can be follow up processing and device finishing operations depending upon the particular application. Modern integrated circuit (IC) fabrication techniques commonly utilize gap fill material such as dielectric materials (e.g., chemical vapor deposition oxide or nitrides) or epoxy molding compound to encapsulate the hybrid bonded dies for various reasons including to protect brittle material from mechanical damage and to smooth out a surface to facilitate downstream wafer-level processing and dicing.

### SUMMARY

Embodiments describe integrated circuit structures and methods for sealing the periphery of a die directly bonded to an electronic component. In an embodiment, side fill material may be located along the periphery of a die, where a bonding surface of the die is directly bonded (e.g., hybrid bonded) to a bonding surface of the electronic component. In such instances, the coefficient of thermal expansion of the side fill material is substantially similar to the coefficient of thermal expansion of the bonding surface of the die, where the side fill material may be applied as an inorganic polymer and then converted to an oxide material (e.g., silicon dioxide). Embodiments also describe electronic packages and methods for bonding a thermal solution to an integrated circuit structure. In an embodiment, a thermal bonding layer may be applied as an inorganic polymer and then converted to an oxide material (e.g., silicon dioxide), where the thermal solution may then be directly bonded (e.g., fusion bonded) to the integrated circuit structure. In an embodiment, the thermal bonding layer may include a matrix of thermally conductive nanoparticles to improve thermal conductivity. In an embodiment, the thermal bonding layer may include a plurality of vias to improve thermal conductivity.

### BRIEF DESCRIPTION OF THE DRAWINGS

FIG. 1A is a cross-sectional side view illustration of an integrated circuit (“IC”) structure with a side fill material in accordance with embodiments.

FIG. 1B is a close-up view of the IC structure with a side fill material illustrated in the example of FIG. 1A.

FIG. 1C is a schematic cross-sectional side view illustration of an IC structure with a recessed die and side fill material in accordance with embodiments.

FIG. 2 is a flow chart of a method for sealing a die periphery in accordance with embodiments.

FIG. 3A-3C are schematic cross-sectional side view illustrations of a method for sealing a die periphery in accordance with embodiments.

FIG. 4A is a schematic cross-sectional side view illustration of an electronic package with a thermal bonding layer in accordance with embodiments.

FIG. 4B is a schematic cross-sectional side view illustration of an electronic package with a thermal bonding layer that includes a plurality vias in accordance with embodiments.

FIG. 4C is a schematic top view illustration of an electronic package with a thermal bonding layer in accordance with embodiments.

FIG. 5 is a flow chart of a method for forming a thermal bonding layer in accordance with embodiments.

FIGS. 6A-6D are schematic cross-sectional side view illustrations of a method for forming a thermal bonding layer in accordance with embodiments.

### DETAILED DESCRIPTION

In direct bonding (e.g. hybrid bonding, fusion bonding, etc.), it has been observed that the bonding strength and bonding quality may be higher in a center region of the die and lower along a peripheral region of the die, such as the sides or lateral edges of the die. Further, these peripheral regions with lower bonding strength and/or quality may become unbonded due to strain experienced by the die during the downstream packaging process, which may lead to delamination. It has been observed that the presence and potential propagation of such defects can lead to diminished reliability and lower yields for hybrid bonded dies. In the embodiments described, the periphery of the dies may be sealed by an inorganic-convertible polymer to improve bond strength and quality along the die periphery. Such inorganic-convertible polymers (e.g., polysilazane, etc.) may be applied to occupy one or more voids created in these unbonded regions and may then be converted to an oxide material, such as SiO₂.

It has also been observed that oxide layers may be utilized to bond mechanical or thermal-mechanical support structures to die-on-wafer or die-on-die hybrid bonding architectures, where such oxide layers may be deposited by chemical vapor deposition (“CVD”), for example. Further, since the topography of CVD-deposited bonding layers must be flattened by chemical mechanical polishing (“CMP”), such bonding layers may be deposited with a high thickness (e.g., greater than 2 μm), where the leftover thickness after the CMP process may still be high (e.g., 1-2 μm). These oxide or dielectric materials have low thermal conductivity, and the thickness of the film can act as a “bottleneck” or thermal barrier that prevents the flow of heat from the die to the thermal-mechanical support. In the embodiments described, thermal bonding layers may be formed with inorganic-convertible polymers (e.g., polysilazane, etc.) that may be converted or activated to an oxide material, such as SiO₂, where such thermal bonding layers may provide the same bonding mechanism but at a reduced thickness. For example, these polymers can be spin-coated which is a self-planarizing process that helps to reduce the thickness. In this way, the reduced thickness of the thermal bonding layer may alleviate the thermal “bottleneck” of conventional methods. In some embodiments, the thermal bonding layers may include a plurality of copper vias to further enhance thermal conductivity. In other embodiments, the thermal bonding layers may include a matrix of thermally conductive nanoparticles to further enhance thermal conductivity.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “over,”, “to”, “between”, and “on” as used herein may refer to a relative position of one layer with respect to other layers. One layer “over”, or “on” another layer or bonded “to” or in “contact” with another layer may be directly in contact with the other layer or may have one or more intervening layers. One layer “between” layers may be directly in contact with the layers or may have one or more intervening layers.

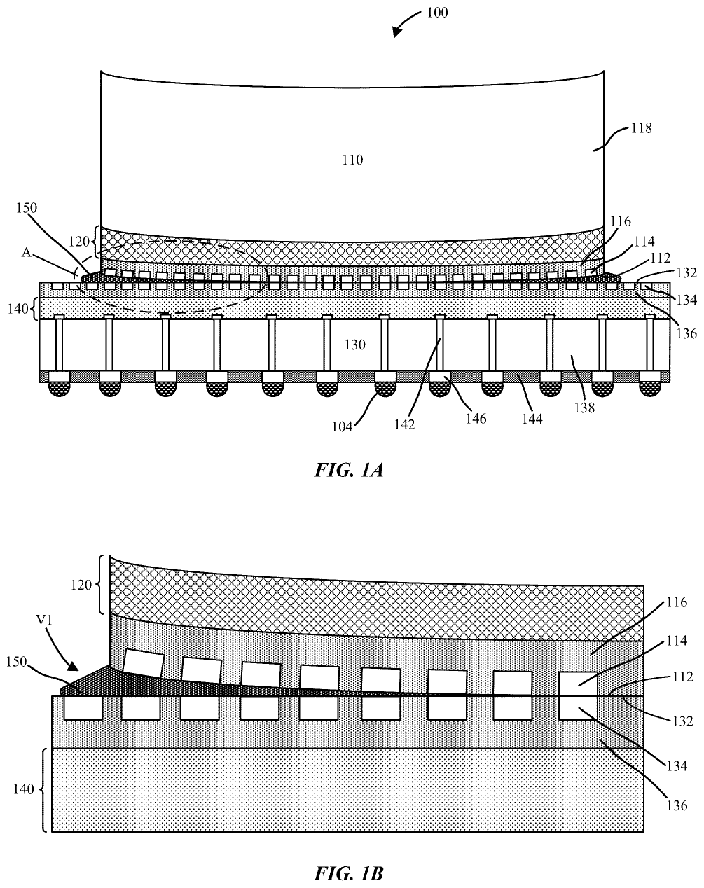

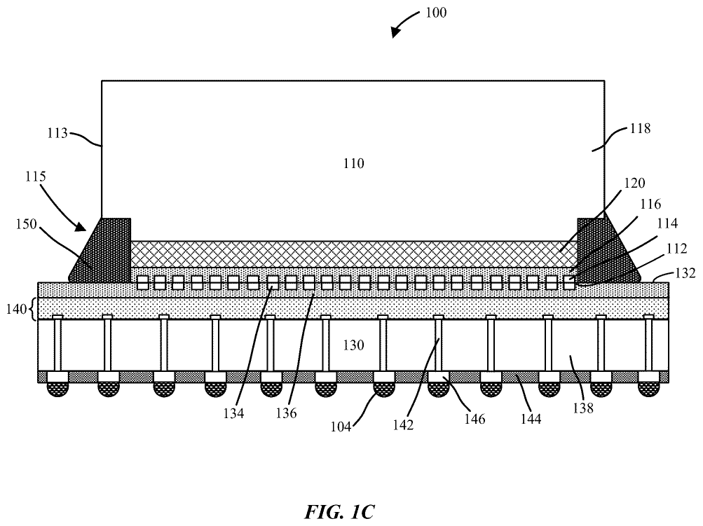

Referring now to FIGS. 1A-1C, FIG. 1A is a schematic cross-sectional side view illustration of an integrated circuit (“IC”) structure with a side fill material in accordance with embodiments; FIG. 1B is a close-up view of the IC structure with a side fill material illustrated in the example of FIG. 1A; FIG. 1C is a schematic cross-sectional side view illustration of an IC structure with a recessed electronic package and side fill material in accordance with embodiments. IC structure 100 may include a plurality of dies bonded to an electronic component. In the example of FIG. 1A, IC structure 100 includes die 110 and electronic component 130. Die 110 may include semiconductor layer 118 and back-end-of-the-line (“BEOL”) build-up structure 120. Semiconductor layer 118 may include a bulk silicon substrate, silicon-on-insulator (“SOI”) substrate, etc. and may also include an epitaxial device layer. It should be noted that silicon is an exemplary substrate material and that other semiconductor substrate materials are contemplated. BEOL build-up structure 120 may include electrical routing as is customary, as well as optional metal sealing structures (e.g., seal rings) to function as both a physical barrier from moisture and impurity ingress, as well as to provide mechanical integrity. Further, BEOL build-up structure 120 may include a plurality of metal wiring layers and dielectric layers, referred to as interlayer dielectrics (“ILD”) as is common in microelectronic manufacturing.

In further reference to FIG. 1A, electronic component 130 can be a variety of components such as a second die, an interposer, etc. Electronic component 130 may include semiconductor layer 138 (which can also be a bulk layer formed of silicon) and BEOL build-up structure 140. Alternatively, semiconductor layer 138 can be substituted with another bulk material, such as glass. BEOL build-up structure 140 may include electrical routing, an optional seal ring, and optionally die-to-die routing between other components that may be bonded to electronic component 130. In addition, a plurality of through vias 142 (e.g., through silicon vias, through glass vias, etc.) can extend through the semiconductor layer 138 and backside layer 144 to make contact with terminals 146, onto which solder bumps 104 (which can also be solder tips) may be placed.

Still referring to FIG. 1A, die 110 may be directly bonded to electronic component 130. Direct bonding may be accomplished using suitable techniques, such as fusion bonding (e.g., dielectric-dielectric bonds) or hybrid bonding (e.g., metal-metal bonds and dielectric-dielectric bonds), where the dielectric materials used by hybrid and/or fusion bonding can be inorganic-based or organic-based materials. For example, die 110 may include bonding surface 112, a plurality of metal bond pads 114, and dielectric bonding layer 116 on BEOL build-up structure 120. Similarly, electronic component 130 may include bonding surface 132, a plurality of metal bond pads 134, and dielectric bonding layer 136 on BEOL build-up structure 140. Further, to facilitate fusion or hybrid bonding, bonding surfaces 112, 132 may be planarized (e.g., chemical mechanical polishing (“CMP”)), where such planarized bonding surfaces may be directly bonded to one another at (and diffused across) a bonding interface.

It has been observed that fusion or hybrid bonding processes may cause residual stress in the BEOL build-up structures and dielectric bonding layers of a die, which may in turn cause a certain level of intrinsic strain in the die. The intrinsic strain may then lead to delamination where the bonds formed during the direct bonding process may become unbonded. Such delamination may initiate along a peripheral region of the bond interface (where the bonds may be weaker) and may even propagate to central or inner regions of the bond interface during subsequent downstream processes (e.g., encapsulation, thermal treatment, etc.). For example, FIG. 1B illustrates a close-up view of section A of FIG. 1A in which void V1 has formed between bonding surface 112 and bonding surface 132. In embodiments, IC structure 100 may include side fill material 150 that may be applied along a periphery of the die, such as the sides or lateral edges of the die, to occupy one or more of the unbonded regions or voids before undergoing subsequent downstream processes, where side fill material 150 may partially or fully occupy such unbonded regions or voids. In this way, “sealing” the die periphery at this phase may limit or prevent further delamination and may also improve the bonding strength between die 110 and electronic component 130. In some embodiments, side fill material 150 may be applied as a “spot fill” to occupy one or more targeted areas around the periphery of the die that have been affected by delamination. In other embodiments, side fill material 150 may be applied to completely surround the periphery of the die, which may include areas affected by delamination as well as areas unaffected by delamination. In other embodiments still, side fill material 150 may be applied before a phase of the direct bonding process that may cause delamination, such as before a clamping phase or before an annealing phase, etc., so that the application of side fill material 150 may act in a preventative manner against the formation of voids.

Side fill material 150 may include polymer materials, such as polysilazanes, that may be converted to an oxide material. Such polymer materials may be designated as perhydropolysilazane, polyperhydridosilazane, inorganic polysilazane, etc. In a particular embodiment, side fill material 150 is perhydropolysilazane (“PHPS”). After an annealing phase of the direct bonding process, side fill material 150 may be applied as the PHPS polymer to a corner, periphery, sidewall, lateral edge, etc. of die 110 by various suitable methods (e.g., jetting, spray coating, etc.), where the polymer may flow to occupy one or more voids that may have been caused by delamination. The PHPS polymer may then be activated or converted into silicon dioxide through various suitable methods, such as annealing, irradiation by a light source (e.g., ultraviolet light (“UV”), infrared light (“IR”), etc.) or laser, treatment with pH-controlled chemicals, exposure to moisture, etc. It should be noted that PHPS activation or conversion into SiO₂ may occur at room temperature by introducing H₂O at the PHPS interface, for example, by plasma hydrophilic treatment. The reaction for the activation or conversion of PHPS into SiO₂ may be summarized as equation (1):

SiH₂NH+2H₂O→SiO₂+NH₃+2H₂ (1)

It has been observed that polysilazane-derived silicon dioxide improves the bond strength at the die periphery and may be characterized as having a coefficient of thermal expansion (“CTE”) that is substantially similar to the die material. Properties of SiO2 converted from PHPS should be close to the bonding surface that will help to eliminate any stress due to mechanical properties mismatch. Further, the conversion of PHPS films to SiO₂ may not be a complete conversion. For example, based on glow discharge optical emission spectroscopy data, it has been observed that polysilazane-derived silicon dioxide may include approximately 10 wt. % of residual nitrogen after conversion. Further still, the refractive index of polysilazane-derived silicon dioxide may be higher than the refractive index of pure SiO₂. For example, based on ellipsometer data, it has been observed that the refractive index of polysilazane-derived silicon dioxide may ranging from 1.45-1.54 based on the curing method, whereas the refractive index of pure SiO₂ may range from 1.45-1.47.

Referring now to FIG. 1C, a schematic cross-sectional side view illustration of an IC structure with a recessed die and side fill material is shown in accordance with embodiments. Side fill material 150 may be utilized not only to occupy or seal unintentional voids that may occur during the direct bonding process as described in the examples of FIGS. 1A-1B, but may also be utilized to occupy or seal “intentional” grooves or recesses incorporated into the die design. In such instances, one or more grooves or edge recesses may be incorporated as part of a die design in order to mitigate stress concentration of a molded, and hybrid or fusion bonded interface. In the example of FIG. 1C, die 110 includes bonding surface 112, lateral edge 113 and edge recess 115, where bonding surface 112 is bonded directly to bonding surface 132 of electronic component 130. In some embodiments, the corner of die 110 may include chamfers or otherwise tapered edges to help prevent stress accumulation at the corners of the bonding interface. In such instances, the one or more edge recesses can be formed by any combination of patterning and etching techniques (e.g., plasma etching, etc.). After formation of the one or more edge recess, such as edge recess 115 in the example of FIG. 1C, side fill material 150 may be applied to occupy the edge recess, where side fill material 150 may then be activated/converted as described above (e.g., annealing, IR irradiation, plasma treatment, etc.).

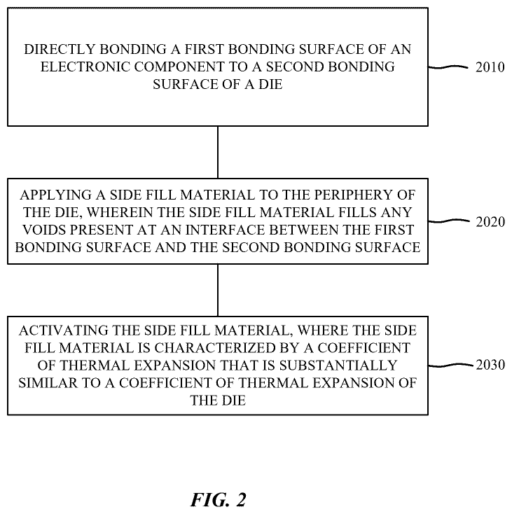

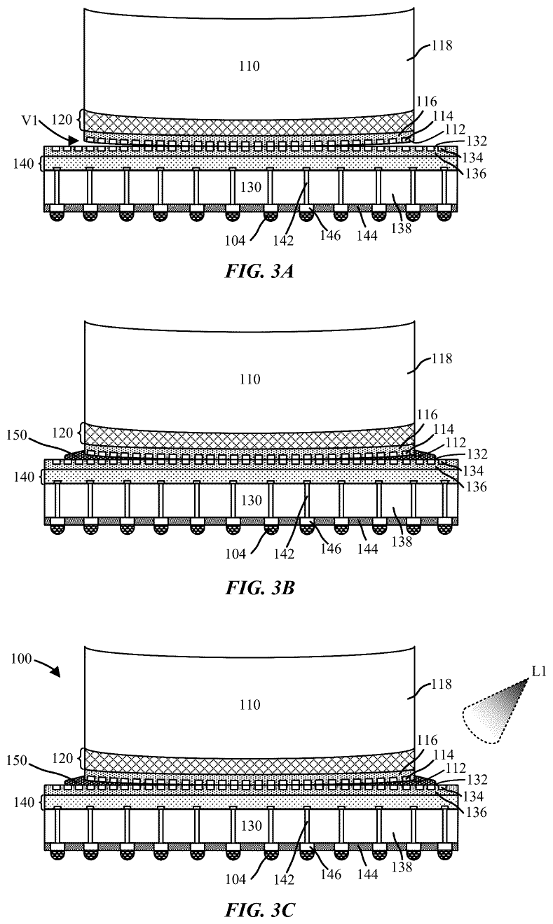

Referring now to FIG. 2 and FIGS. 3A-3C, FIG. 2 is a flow chart and FIGS. 3A-3C are schematic cross-sectional side view illustrations of a method for sealing a die periphery. In the interest of clarity and conciseness, the method of FIG. 2 is described concurrently with the illustrations of FIGS. 3A-3C. At operation 3010, bonding surface 112 of die 110 may be directly bonded (e.g., fusion bonded, hybrid bonded, etc.) to bonding surface 132 of electronic component 130. In some instances, the die warpage may cause voids after the bonding process at the periphery between bonding surface 112 of die 110 and bonding surface 132 of electronic component 130, as illustrated in FIG. 3A. Typically, the voids may form along the peripheral region of the interface between the die and the electronic component, but such voids may also form (or propagate to) a central or inner region of the interface between the die and the electronic component. At operation 3020, side fill material 150 (e.g., PHPS) may be applied to the periphery of die 110 to occupy one or more voids that may have formed at the interface between bonding surface 112 of die 110 and bonding surface 132 of electronic component 130 (e.g., jetting, spray coating, etc.). It should be noted that side fill material 150 is applied as a PHPS polymer (before activation) where its flow characteristics are such that the PHPS may occupy one or more of the voids located along a peripheral region of the interface between die 110 and electronic component 130, and, if such voids have propagated to an inner region of the interface, the PHPS may also flow to the inner region of the interface. Further, at operation 3030, side fill material 150 may be activated to convert the PHPS into SiO₂ (e.g., annealing, IR irradiation, plasma treatment, etc.). In the example of FIG. 3C, side fill material 150 is irradiated by UV light, L1. It should be noted that side fill material 150 has a CTE compatible with the bonding surface dielectric, such as dielectric bonding layer 116. In this way, by occupying the voids with side fill material 150 before subsequent downstream processes, such as encapsulation for example, side fill material 150 may prevent gap-fill material such as molding compound (e.g., epoxy molding compound (“EMC”)) from entering such voids and ultimately propagating such voids due to the mismatched CTE of the molding compound and the die it encapsulates.

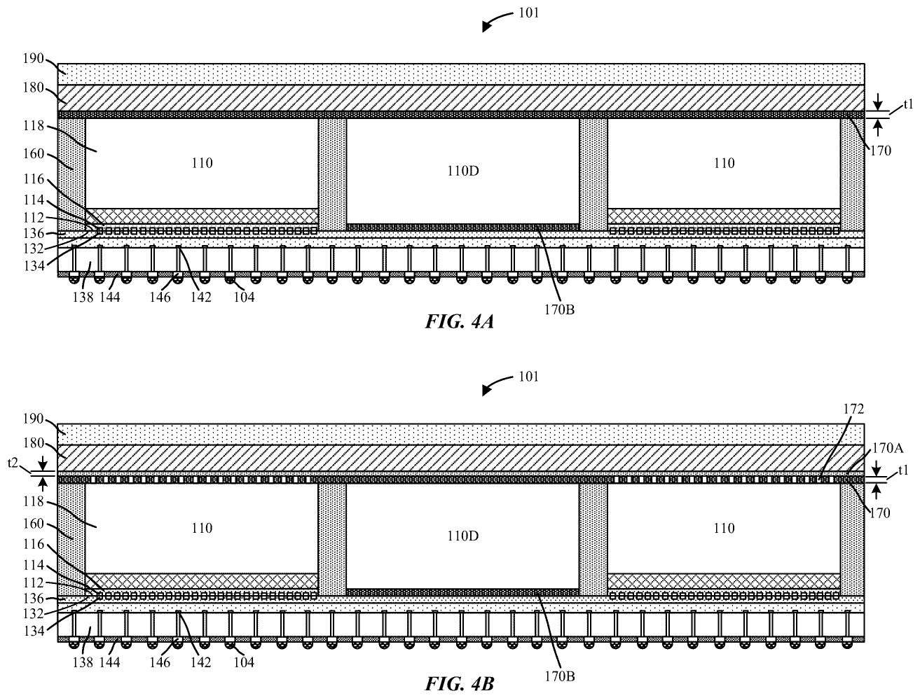

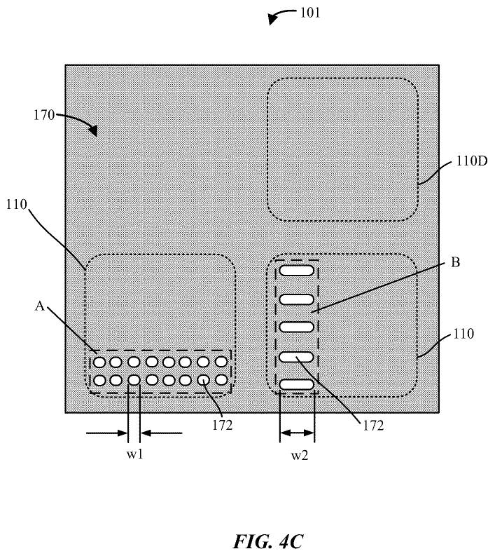

Referring now to FIGS. 4A-4C, FIG. 4A is a schematic cross-sectional side view illustration of an electronic package with a thermal bonding layer in accordance with embodiments; FIG. 4B is a schematic cross-sectional side view illustration of an electronic package with a thermal bonding layer that includes a plurality of vias in accordance with embodiments; and FIG. 4C is a schematic top view illustration of an electronic package with a thermal bonding layer in accordance with embodiments. Electronic package 101 may include a plurality of dies bonded to an electronic component. For example, in FIG. 4A, electronic package 101 includes a plurality of dies, such as die 110, and electronic component 130. Die 110 may include semiconductor layer 118 (e.g., silicon substrate, epitaxial layer, etc.) and BEOL build-up structure 120 with optional metal sealing structures (e.g., seal rings) as well as a plurality of metal wiring and dielectric layers (e.g., ILD), similar to the example described in FIG. 1A. Further, electronic component 130 (e.g., die, interposer, etc.) may include semiconductor layer 138 (e.g., silicon, glass, etc.), BEOL build-up structure 140 (e.g., electrical routing, seal ring, die-to-die routing, etc.) as well as a plurality of through vias 142 (e.g., through silicon vias, through glass vias, etc.) that extend through the semiconductor layer 138 and backside layer 144 to make contact with terminals 146, onto which solder bumps 104 (which can also be solder tips) may be placed, similar to the example described in FIG. 1A.

In further reference to FIG. 4A, die 110 may include a bonding surface 112, a plurality of metal bond pads 114, and dielectric bonding layer 116 on BEOL build-up structure 120. Further, electronic component 130 may include bonding surface 132, a plurality of metal bond pads 134, and dielectric bonding layer 136 on BEOL build-up structure 140. In embodiments, bonding surface 112 of die 110 may be directly bonded (e.g., hybrid bonded, etc.) to bonding surface 132 of electronic component 130. After the direct bonding process, electronic package 101 may undergo further fabrication processes, such as sealing of the die periphery as described in the examples of FIGS. 1A-1C, FIG. 2 and FIGS. 3A-3B. In addition, a molding process may then be performed where gap fill material 160 (e.g., epoxy molding compound (“EMC”), etc.) may laterally surround the plurality of dies and fill the spaces between dies. The molding process may then be followed by a grinding operation to expose the dies, which may form top surface 111 that includes the exposed dies and gap fill material 160. Further, thermal solution 180 (e.g., thermal lid, heat sink, heat spreader, etc.) may be formed over top surface 111. Thermal solution 180 can be a single layer or material, or may be a combination of multiple layers, materials and structures. For example, thermal solution 180 can be formed of a variety of thermally conductive materials, including metal, aluminum nitride, silicon, diamond, silicon carbide, etc. Thermal solution 180 may also provide mechanical support, and thus function as a thermal-mechanical solution. In an embodiment, the thermal solution is formed of a silicon substrate, which has sufficient thermal conductivity to function as a heat sink and a CTE compatible with die materials. In addition, electronic package 101 may include thermal interface material 190 (e.g., thermal adhesive, thermal paste, thermally conductive pad, etc.) bonded to thermal solution 180. Thermal interface material 190 may be formed of any suitable thermally conductive material and may act as a heat sink between electronic package 101 and another device, component, etc., mounted to the package.

Still referring to FIG. 4A, electronic package 101 may also include a thermal bonding layer 170 to bond (e.g., fusion bond, etc.) top surface 111 to thermal solution 180. It has been observed that conventional bonding layers (e.g., oxide, metal, solder, etc.) require planarization processes to ensure the proper density and uniformity of such layers. Further, it has been observed that conventional bonding layers may be in the range of 1-2 microns or even thicker, which may contribute to the thermal impedance of such layers. In embodiments, thermal bonding layer 170 may be formed of polymer materials such as polysilazanes (perhydropolysilazane, polyperhydridosilazane, inorganic polysilazane, etc.), which may then be converted to an oxide material in accordance with the chemical reaction summarized in equation (1) above. Further, such conversion may occur in the same manner described for side fill material 150 in the example of FIGS. 1A-1C (e.g., annealing, IR irradiation, plasma treatment, etc.). In a particular embodiment, thermal bonding layer 170 is a perhydropolysilazane polymer (“PHPS”) that may be formed by spin coating, which is a self-planarizing process thereby eliminating the need for chemical mechanical polishing and the greater film thicknesses associated with chemical mechanical polishing. In this way, thermal bonding layer 170 may achieve thicknesses significantly thinner than conventional bonding layers. For example, the thickness of thermal bonding layer 170, t1, may be approximately 40-100 nanometers. In addition, thermal bonding layer 170 may be porous, where a density of thermal bonding layer 170, such as silicon dioxide, may have a lower density than a silicon dioxide layer formed by chemical vapor deposition. For example, it has been observed that polysilazane-derived silicon dioxide layers formed in a manner similar to thermal bonding layer 170 may have a density in the range of 1.6-2.0 g/ml after curing, as opposed to silicon dioxide layers formed by chemical vapor deposition, which may have a density in the range of 2.03-2.24 g/ml.

In further reference to FIG. 4A, die 110 may be replaced by a dummy feature, such as 110D, to provide mechanical stability, aid in singulation, etc., where such dummy features may approximate the shape and size of a die (e.g., die 110). In some embodiments, dummy feature 110D may be formed entirely of the same polymer material described in reference to side fill material 150 and thermal bonding layer 170 (e.g., polysilazanes), as opposed to conventional methods in which dummy features may include copper, dielectric patterns and other costly materials. Further, the dummy feature may be formed in a manner similar to thermal bonding layer 170 (e.g., spin coating, etc.), as opposed to conventional methods in which dummy features may undergo a direct bonding process that involves complex preparation and extended cycle times. In this way, the dummy features formed of polysilazane-derived SiO₂ present a relatively low-cost option to conventional dummy feature compositions and methods. In other embodiments, dummy feature 110D may be composed of any suitable die material (e.g., silicon) and may include copper, dielectric patterns, etc., where such dummy features may be bonded to electronic component 130 by thermal bonding layer 170B, as illustrated in FIG. 4A. In such instances, thermal bonding layer 170B may be formed as described above (e.g., spin coated, cured, etc.) on a silicon wafer, for example, where the silicon wafer may be diced to form dummy feature 110D and then bonded (e.g., fusion bonded) to electronic component 130.

Referring now to FIG. 4B, a schematic cross-sectional side view illustration of a thermal bonding layer that includes a plurality of vias is shown in accordance with embodiments. In embodiments, thermal bonding layer 170 can include features to further enhance its thermal conductivity. In one embodiment, thermal bonding layer 170 may include a plurality of vias to further enhance the thermal conductivity of the bonding layer, where he plurality of vias may be of any size, shape, number of vias, etc., and may be formed of copper or any other material suitable for conducting heat from die 110 to thermal solution 180. In some examples, the plurality of vias 172 may be patterned, where the patterning of the plurality of vias 172 may occur after the formation of thermal bonding layer 170 or before formation of thermal bonding layer 170. In instances where the patterning of the plurality of vias 172 may occur after formation of thermal bonding layer 170, the inorganic-convertible polymer (e.g., polysilazanes, etc.) may be deposited on top surface 111 and activated/converted to form a silicon dioxide layer, for example, where the silicon dioxide layer may then be patterned to form the plurality of vias 172. In instances where the patterning of the plurality of vias 172 may occur before formation of thermal bonding layer 170, the plurality of vias 172 may be patterned on a top surface of a die (e.g., die 110), where the inorganic-convertible polymer (e.g., polysilazanes, etc.) may then be deposited on top surface 111 to fill the gaps between vias and activated/converted to form a silicon dioxide layer that includes the previously formed vias. In other examples, the plurality of vias 172 may be drilled through the top side of the thermal bonding layer 170. Further, an additional thermal bonding layer, such as thermal bonding layer 170A, may be formed over the plurality of vias 172 to enhance the bonding surface for bonding to thermal solution 180. In such instances, the thickness, t2, of thermal bonding layer 170A may be less than the thickness, t1, of thermal bonding layer 170. In addition, the location of the plurality of vias 172 may be based on the location of “hot spots” on electronic package 101. For example, some areas of an electronic package may experience higher temperatures or thermal loads than other areas, where the plurality of vias may be grouped or located in these higher temperature/thermal load areas to aid in conducting the heat away from die 110 and toward thermal solution 180. In another embodiment, thermal bonding layer 170 may include a matrix of thermally conductive nanoparticles to further enhance the thermal conductivity of the bonding layer. For example, the thermally conductive nanoparticles may be incorporated into the inorganic-convertible polymer (e.g., polysilazane, etc.) before activation or conversion, where the polymer solution that includes the thermally conductive nanoparticles may then be spin-coated and activated/converted (e.g. cured) for bonding to thermal solution 180 in the same manner described above (e.g., fusion bonding). In such instances, the particles size of the thermally conductive nanoparticles may be in the micron to submicron range, where the particles may be metal-based (e.g., copper, etc.) or ceramic-based.

Referring now to FIG. 4C, a schematic top view illustration of electronic package 101 with thermal bonding layer 170 is shown (before depositing thermal bonding layer 170A and bonding thermal solution 180). In the example of FIG. 4C, area A may experience high thermal loads and, as such, may include a plurality of vias 172 grouped in area A. Similarly, area B may also experience high thermal loads and, as such, may include a plurality of vias 172 grouped in area B. It should also be noted that, as illustrated in the example of FIG. 4C, the location of the plurality of vias may vary from die-to-die. In addition, the plurality of vias 172 may be of any size or shape, where the size and the shape of the plurality of vias may also vary from die-to-die. For example, as illustrated in FIG. 4C, the size of the plurality of vias 172 in area A, w1, is different from the size of the plurality of vias 172 in area B, w2. In addition, the circular shape of the plurality of vias 172 in area A is different from the oblong shape of the plurality of vias 172 in area B. Further, the example of FIG. 4C also includes a dummy feature 110D formed of polysilazane-derived silicon dioxide.

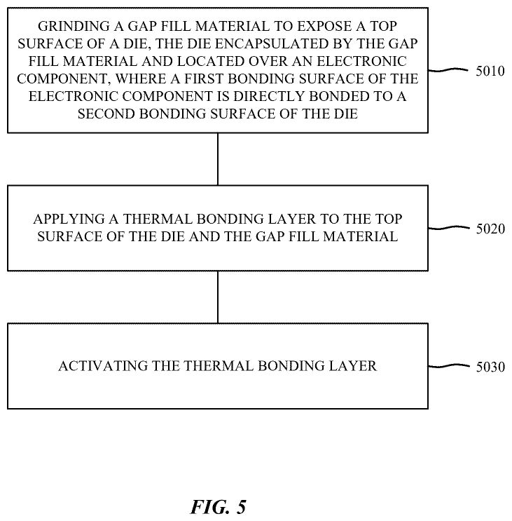

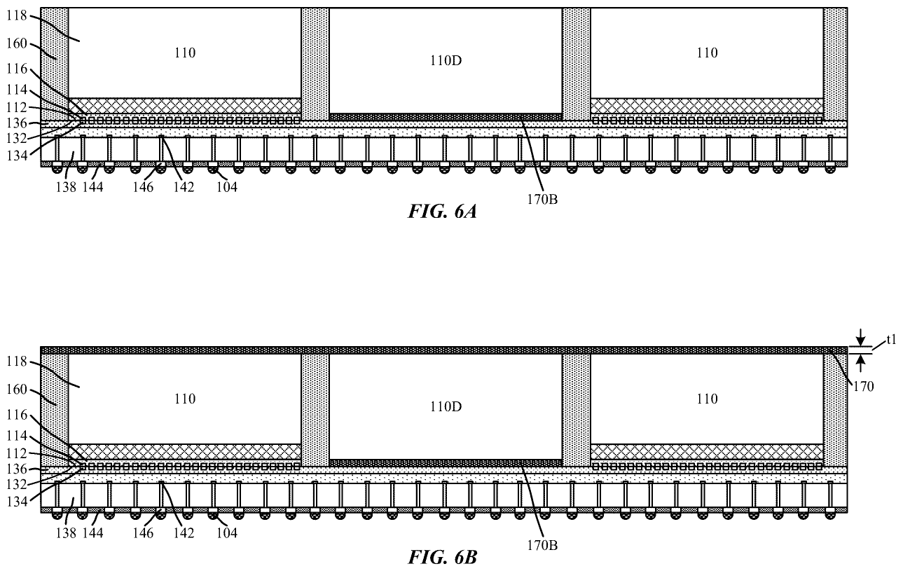

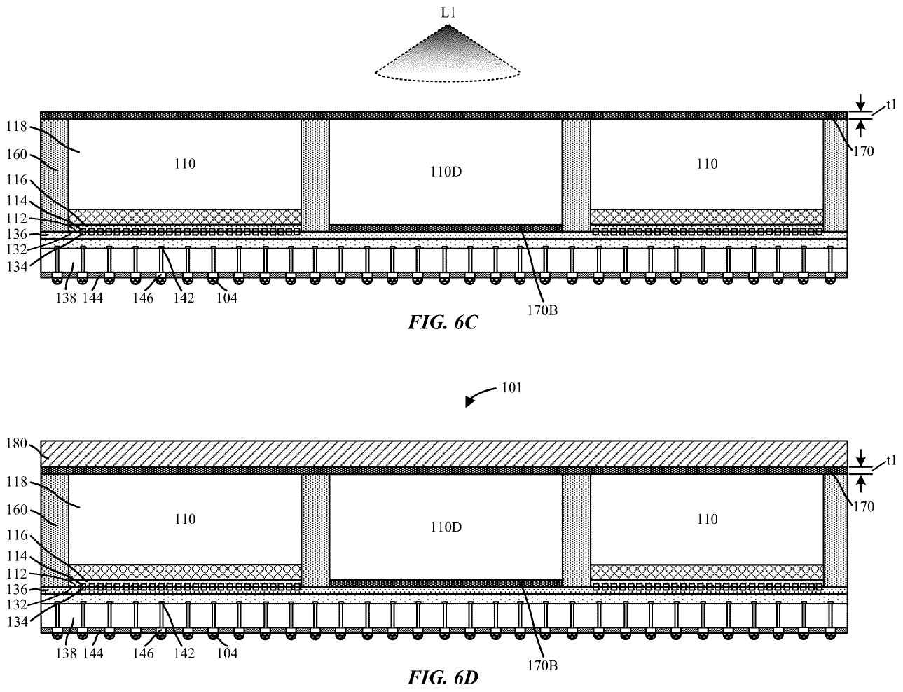

Referring now to FIG. 5 and FIGS. 6A-6D, FIG. 5 is a flow chart and FIGS. 6A-6C are schematic cross-sectional side view illustrations of a method for forming a thermal bonding layer. In the interest of clarity and conciseness, the method of FIG. 5 is described concurrently with the illustrations of FIGS. 6A-6C. At operation 5010, a grinding operation may be performed to expose die 110 and form top surface 111, where die 110 may be encapsulated by gap fill material 160 (e.g., epoxy molding compound (“EMC”), etc.) and directly bonded (e.g., hybrid bonded, etc.) to electronic component 130. In some embodiments, die 110 may be replaced by a dummy feature, such as dummy feature 110D, where the dummy feature may be composed entirely of the same inorganic-convertible polymer material as thermal bonding layer 170 (e.g., polysilazanes). In such instances, the dummy feature may be formed by spin coating or any other suitable method and may then be activated or converted into SiO₂ (e.g., annealing, IR irradiation, plasma treatment, etc.) In other embodiments, dummy feature 110D maybe be composed of any suitable die material (e.g., silicon) that may then be coated with the inorganic-convertible polymer material (e.g., polysilazanes), converted to form thermal bonding layer 170B, and bonded (e.g., fusion bonded) to electronic component 130, as illustrated in FIG. 6B. At operation 5020, thermal bonding layer 170 may be formed on top surface 111 by any suitable method (e.g., spin coating). In such instances, thermal bonding layer 170 may be applied as a polymer material (e.g., polysilazane, etc.) before activation/conversion into an oxide layer, where a thickness, t1, of thermal bonding layer 170 may be approximately 40-100 nanometers, for example. In this way, thermal bonding layer 170 may have a reduced thickness (and in turn a reduced thermal impedance) and may be formed by lower-cost planarization techniques as compared to conventional bonding layers.

At operation 5030, thermal bonding layer 170 may then be activated to convert the PHPS into SiO₂ (e.g., annealing, IR irradiation, plasma treatment, etc.). In the example of FIG. 6C, thermal bonding layer 170 is irradiated by UV light, L1. In embodiments, thermal bonding layer 170 can include features to further enhance its thermal conductivity. In some embodiments, thermal bonding layer 170 may include a matrix of thermally conductive nanoparticles (e.g., copper, etc.) to further enhance the thermal conductivity of thermal bonding layer 170, where the PHPS solution may include thermally conductive nanoparticles (e.g., copper) that may be spin-coated and cured in the same manner described above. In other embodiments, thermal bonding layer 170 may include a plurality of vias to further enhance the thermal conductivity of thermal bonding layer 170, where the plurality of vias 172 may be formed by any suitable method (e.g., patterned, drilled, etc.), composed of any suitable material (e.g., copper, etc.) and may be of any size, shape (e.g., circular, oblong, etc.), number, etc., similar to the example of FIG. 4B. Further, where the plurality of vias 172 are patterned, the patterning may occur after the formation of thermal bonding layer 170 or before the formation of thermal bonding layer 170, as described in the example of FIG. 4B. In addition, the sizes, shapes, numbers, etc. of the plurality of vias may vary from die-to-die based on the location of high thermal load areas experienced by electronic package 101, similar to the example of FIG. 4C. In such instances where thermal bonding layer 170 includes a plurality of vias 172, another thin thermal bonding layer (e.g., 0.2 micron) may be formed over the plurality of vias 172 to ensure a strong enough bond with thermal solution 180, such as thermal bonding layer 170A illustrated in FIG. 4B. In another embodiment still, thermal solution 180 (e.g., thermal lid, heat sink, heat spreader, etc.) may then be formed over the thermal bonding layer 170.

In utilizing the various aspects of the embodiments, it would become apparent to one skilled in the art that combinations or variations of the above embodiments are possible for sealing a die periphery and forming a thermal bonding layer. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. An integrated circuit (“IC”) structure comprising:
an electronic component including a first bonding surface;
a die including a second bonding surface, the second bonding surface directly bonded to the first bonding surface; and
a side fill material along a periphery of the die, the side fill material being characterized by a coefficient of thermal expansion that is substantially similar to a coefficient of thermal expansion of the second bonding surface, wherein the side fill material occupies one or more voids present at an interface between the first bonding surface and the second bonding surface.

2. The IC structure of claim 1, wherein the electronic component is an interposer, and the die includes a semiconductor layer on a back-end-of-the-line (“BEOL”) build-up structure.

3. The IC structure of claim 1, wherein the side fill material is silicon dioxide or other inorganic dielectrics.

4. The IC structure of claim 1, wherein directly bonding the die to the electronic component includes hybrid bonding the first bonding surface of the electronic component to the second bonding surface of the die.

5. The IC structure of claim 1, wherein the die includes a recess along the periphery and the side fill material occupies the recess.

6. A method for sealing a die periphery comprising:
directly bonding a first bonding surface of an electronic component to a second bonding surface of a die;
applying a side fill material to a periphery of the die, wherein the side fill material occupies one or more voids present at an interface between the first bonding surface and the second bonding surface; and
activating the side fill material, wherein the side fill material is characterized by a coefficient of thermal expansion that is substantially similar to a coefficient of thermal expansion of the second bonding surface.

7. The method of claim 6, wherein the side fill material is a polysilazane and activating the polysilazane converts the side fill material to silicon dioxide.

8. The method of claim 6, wherein activating the side fill material includes curing the side fill material with ultraviolet light or laser.

9. The method of claim 6, wherein activating the side fill material includes heating the side fill material.

10. The method of claim 6, wherein activating the side fill material includes plasma treating the side fill material.

11. An electronic package comprising:
an electronic component including a first bonding surface;
a die including a second bonding surface, the second bonding surface directly bonded to the first bonding surface;
a gap fill material to encapsulate the die; and
a thermal solution over the die;
wherein a thermal bonding layer bonds the die to the thermal solution.

12. The electronic package of claim 11, wherein the electronic component is an interposer, and the die includes a semiconductor layer on a back-end-of-the-line (“BEOL”) build-up structure.

13. The electronic package of claim 11, wherein the thermal bonding layer is silicon dioxide or other inorganic dielectrics.

14. The electronic package of claim 11, wherein the thermal bonding layer includes a matrix of thermally conductive nanoparticles.

15. The electronic package of claim 11, wherein the thermal bonding layer has a density ranging from 1.6-2.0 g/ml after curing.

16. The electronic package of claim 11, wherein directly bonding the die to the electronic component includes hybrid bonding the first bonding surface of the electronic component to the second bonding surface of the die.

17. The electronic package of claim 11, wherein the thermal bonding layer includes a plurality of vias, the plurality of vias being formed of copper and located over the die.

18. The electronic package of claim 17, further comprising a second thermal bonding layer over the plurality of vias.

19. The electronic package of claim 11, further comprising a second die, wherein the second die is an active die or a dummy feature, the dummy feature comprising a same material as the thermal bonding layer.

20. The electronic package of claim 11, further comprising a second die, wherein the second die is an active die or a dummy feature, the dummy feature being bonded to the electronic component with another thermal bonding layer.

21. The electronic package of claim 11, wherein the thermal bonding layer comprises residual nitrogen.

22. The electronic package of claim 11, wherein the thermal bonding layer has a refractive index between 1.45 and 1.54.

23. A method for forming an electronic package comprising:
grinding a gap fill material to expose a top surface of a die, the die encapsulated by the gap fill material and located over an electronic component, wherein a first bonding surface of the electronic component is directly bonded to a second bonding surface of the die;
applying a thermal bonding layer to the top surface of the die and the gap fill material; and
activating the thermal bonding layer.

24. The method of claim 23, wherein the thermal bonding layer is a polysilazane and activating the polysilazane converts the thermal bonding layer to silicon dioxide.

25. The method of claim 23, further comprising forming a plurality of vias in the thermal bonding layer, the plurality of vias being formed of copper and located over the die, wherein forming the plurality of vias occurs before or after applying the thermal bonding layer to the top surface of the die and the gap fill material.

26. The method of claim 25, further comprising forming a second thermal bonding layer over the plurality of vias.

27. The method of claim 23, further comprising a second die, wherein the second die is an active die or a dummy feature, the dummy feature being comprising a same material as the thermal bonding layer.

28. The method of claim 23, further comprising a second die, wherein the second die is an active die or a dummy feature, the dummy feature being bonded to the electronic component with another thermal bonding layer.

29. The method of claim 23, wherein the thermal bonding layer includes a matrix of thermally conductive nanoparticles.

30. The method of claim 23, wherein the thermal bonding layer comprises residual nitrogen after activating the thermal bonding layer.

31. The method of claim 23, wherein the thermal bonding layer has a refractive index between 1.45 and 1.54.
